(19) United States
(12) Patent Application Publication
(10) Pub. No.: US 2008/0096426 A1
(43) Pub. Date: Apr. 24, 2008

(54) Coupling device for testing antenna

(75) Inventors: Hung-Ya Chou Huang, Hsin Chu City (TW); Chiu-Ching Yu, Tai Chung Hsien (TW)

Correspondence Address: TROXELL LAW OFFICE PLLC;SUITE 1404, 5205 LEESBURG PIKE, FALLS CHURCH, VA, 22041, US

(73) Assignee: Z-COM, INC.

(21) Appl. No.: 11/583,972

(22) Filed: Oct. 20, 2006

(51) Int. Cl. G01R 29/08

(52) U.S. Cl. 439/620.01

(57) ABSTRACT

A coupling device that is used to test power or field effects of an antenna built into an antenna device is proposed. The antenna device is plate-shaped. The coupling device has a housing, an isolation material, and a connector. The housing has a socket at one side. The socket is capable of receiving the antenna device. The isolation material is disposed inside the socket of the housing. The isolation material has a chamber and a metal plate attached to an inner wall of the chamber. The connector is disposed at another side of the housing. The connector is connected to the metal plate and the metal plate is connected to the housing.

### BACKGROUND OF THE INVENTION

1. Field of the Invention

The present invention is related to a coupling device used for testing an antenna, and more particularly to a coupling device that is used to test an antenna built into a circuit board.

2. Description of Related Art

In general, electronic products with antennas must pass power or field-effect tests before being placed on the market. Two conventional testing methods are disclosed as follows.

In the first method, a transmission line is needed for passing signals to a testing instrument. This method needs to have an external connector to pass signals to the testing instrument.

In the second method, an antenna of a device undergoing a test and an antenna of a receiving end are placed inside an isolation chamber for testing. In this way, the leakage of electric power is prevented, and interference from other products is avoided.

Both methods are flawed. Whether connecting to an external connector or using an isolation chamber, both methods make the testing procedure complicated and costly. Furthermore, both methods can only be used to test antennas with round poles. They cannot be used to test the “on-board antennas”, i.e. antennas built into circuit boards. Since the on-board antennas can be built into the circuit boards without extending therefrom, they have already become a mainstream device. However, there are still test devices that do not have the drawbacks mentioned above and can be used to test the on-board antennas.

### SUMMARY OF THE INVENTION

An objective of the present invention is to provide a coupling device for testing an antenna device without connecting to an external connector or using an additional isolation chamber. The coupling device has a connecting means and hence doesn't need to connect to other external connectors. Moreover, the coupling device itself can prevent electric power from leaking and hence an additional isolation chamber is not necessary. Therefore, by using the coupling device of the present invention, the test procedure can be performed easily and its cost can be reduced. In addition, the coupling device of the present invention can be used to test on-board antennas.

For achieving the objectives above, the present invention provides a coupling device used to test an antenna device. The coupling device includes a housing, an isolation material, and a connector. The housing has a socket at one side. The socket is capable of receiving the antenna device. The isolation material is disposed inside the socket of the housing. The isolation material has a chamber and a metal plate attached to an inner wall of the chamber. The connector is disposed at another side of the housing. The connector is connected to the metal plate and the metal plate is connected to the housing.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is an exploded view of a coupling device in accordance with the present invention;

FIG. 2 is a combinative view of the coupling device in accordance with the present invention;

FIG. 3 is a front view of the isolation material of the coupling device in accordance with the present invention;

FIG. 4 is a cross-sectional view of the isolation material along the line 4-4 shown in FIG. 3;

FIG. 5 shows how the coupling device of the present invention is used to test the antenna device; and

FIG. 6 is a schematic view showing a test architecture that uses the coupling device in accordance with the present invention.

### DETAILED DESCRIPTION OF PREFERRED EMBODIMENTS

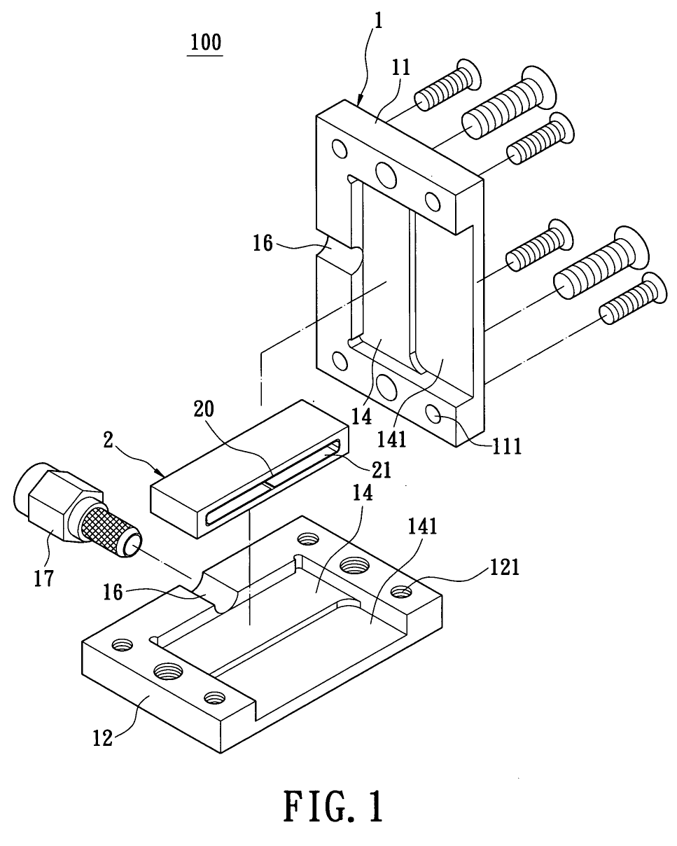

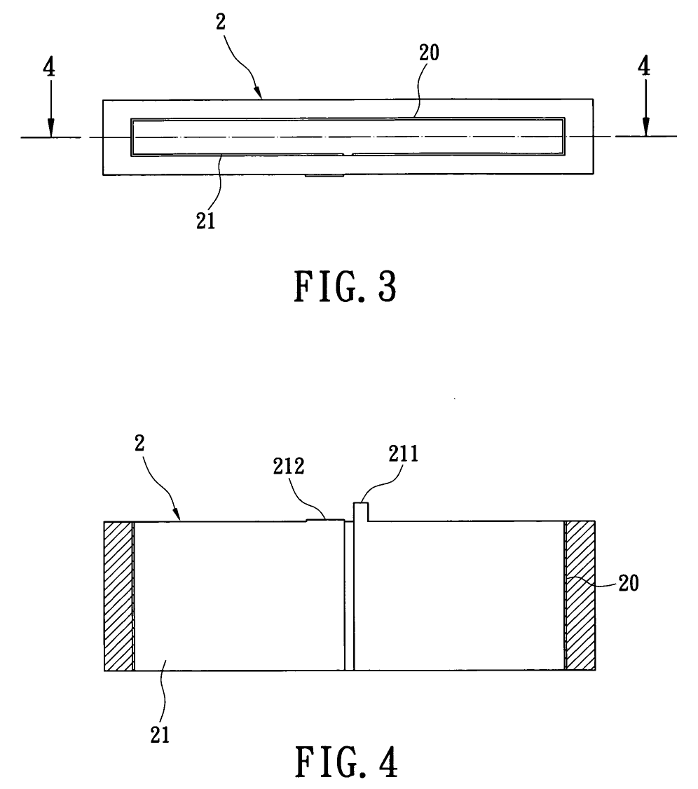

Reference is made to FIGS. 1-6. The present invention provides a coupling device 100 for testing antennas. The coupling device 100 is used to test an antenna device 300, which is plate-shaped. The antenna device 300 is a circuit board 3 having an antenna 4 built therein. The coupling device 100 is used to test the power and field effect of the antenna 4.

The coupling device 100 has a housing 1, an isolation component 2 disposed within the housing 1, and a connector 17 disposed on the housing 1. The housing 1 is made of aluminum or aluminum alloy. It can prevent electric power from leaking, as does the conventional isolation chamber. The isolation component 2 is made of bakelite or other appropriate isolation materials.

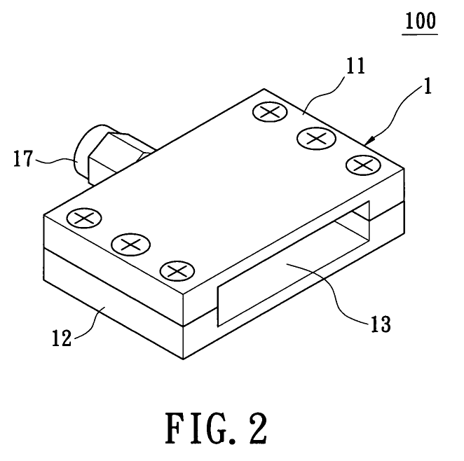

The housing 1 has a socket 13 at one side, as shown in FIG. 2. The socket 13 provides a room to receive the antenna device 300. Hence, the antenna device 300 can be plugged into the socket 13 of the housing for testing.

The isolation component 2 is fixedly disposed in the socket 13 of the house 1. The isolation component 2 has a chamber 20 formed therein and the chamber 20 has two openings in two sides thereof. The openings are aligned in the direction of the socket 13. A metal plate 21 is attached to the inner wall of the chamber 20 of the isolation component 2 via adhesion. The metal plate 21 has a grounding portion 212 and a connecting portion 211. The connecting portion 211 is used to connect to the connector 17 and the grounding portion 212 is used to connect to the ground.

The connector 17 is disposed at a side of the housing 1 and has an end connecting to the connecting portion 211 of the metal plate 21 and another end connecting to a signal transmission line.

The housing 1 can be formed integrally, as mentioned above, or in combination, as shown in the figures. The combinative housing 1 includes a first shell 11 and a second shell 12 that can be combined together. The inner surfaces of the first shell 11 and the second shell 12 both have indentations 14. Each of the indentations 14 has an enlarged portion 141. The socket 13 is formed by combining the indentations 14. The enlarged portions 141 are located at the front end of the socket 13. Hence, the front end of the socket 13 is larger than the rear end. Since the front end of the socket 13 is larger, the socket 13 can be prevented from contacting the electronic components of the antenna device 300. The rear end of the socket 13 is used for disposition of the isolation component 2. The first shell 11 and the second shell 12 respectively have concave portions 16 for clamping the connector 17. The connecting portion 211 of the metal plate 21 is connected to the connector 17 for transmitting signals. The grounding portion 212 is connected to the housing 1. For combination, the first shell 11 and the second shell 12 respectively have multiple holes 111 and 121. By using multiple fixing components as well as the holes 111 and 121, the first shell 11 and the second shell 12 can be combined together. In this way, the coupling device 100 is formed.

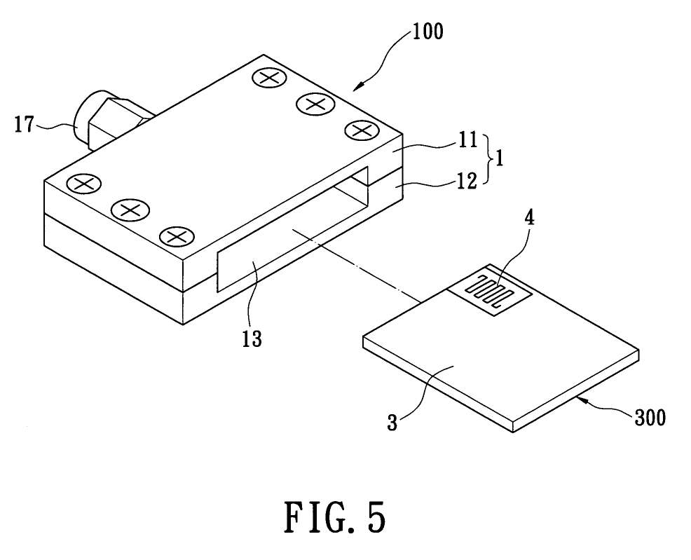

The coupling device 100 is used especially to test plate-shaped antenna devices, such as the antenna device 300 shown in FIG. 5. The antenna device 300 is a circuit board 3 having an antenna 4 built therein and other electronic components.

Reference is made to FIG. 5, which shows how the coupling device of the present invention is used to test the plate-shaped antenna device 300. Since the socket 13 is formed as a slot and the chamber 20 of the isolation material 2 is also formed as a slot, the plate-shaped antenna device 300 can be completely plugged into the socket 13 and the portion of the circuit board 3, including placement of the antenna 4 inside the chamber 20 of the isolation material 2. The antenna 4 can thus be surrounded by the metal plate 221. Hence, the operation of testing the power and field effect of the antenna 4 of the circuit board 3 can be performed. The testing results can be passed to the connector 17 via the connecting portion 211 and then sent out via the connector 17.

In the coupling device 100, the socket 13 of the housing 1 and chamber 20 of the isolation material 2 are formed as slots. Hence, the coupling device 100 is suitable to test the plate-shaped antenna device 300. As shown in the figures mentioned above, when the antenna device 300 is plugged into the socket 13 of the coupling device 100, the distance between the circuit board 3 and the metal plate 21 is very short and the power loss can thus be reduced. In practice, since the shape and size of the socket 13 and the chamber 20 can be designed according to the shape and size of the antenna device 300, an antenna device 300 of any size or shape can be completely plugged into the socket 13 and the chamber 20. Hence, the distance between the circuit board 3 and the metal plate 21 can be further reduced via proper design and the power loss can be further reduced in this way. Moreover, the housing 1 is made of aluminum or aluminum alloy. Hence, it can prevent electric power from leaking, as does the conventional isolation chamber.

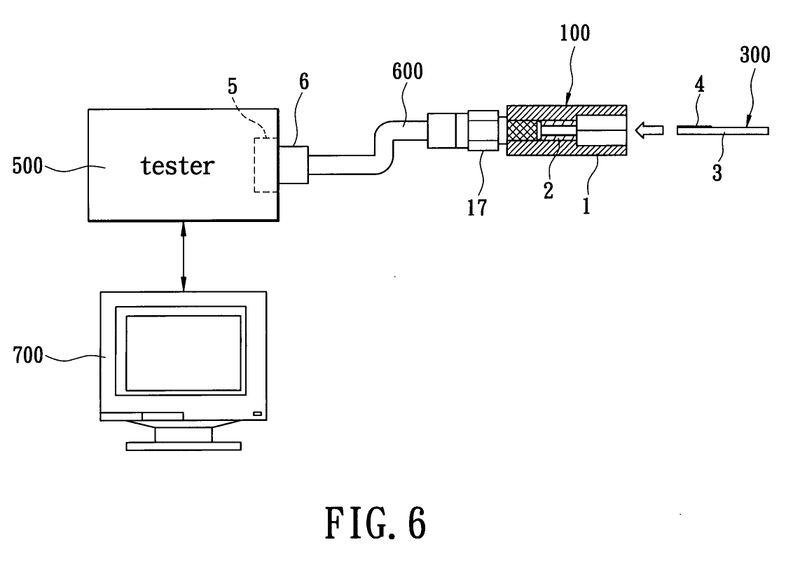

Reference is made to FIG. 6. The coupling device 100 needs to connect to a tester 500. The tester 500 has a connector 5. The connector 5 is connected to the connector 17 via a transmission line 600. Each end of the transmission line 600 has a connector (not shown). A near end of the transmission line 600 has a near-end connector used to connect with the connector 17 while a remote end of the transmission line 600 has a remote-end connector 6 used to connect with the connector 5 of the tester 500. The transmission line 600 can thus be used to transmit signals. The remote-end connector 6 and the connector 5 can be, for example, USB, Mini USB, or 1394 connectors. The tester 500 can be connected to a computer 700 for transferring data, displaying or storing the test results, or showing characteristic curves of the test results.

As described above, the present invention has the advantages as follows.
(1) Due to the specific design of the coupling device 100, the coupling device 100 can be used to test the power or field effect of plate-shaped antenna devices.
(2) The coupling device 100 itself has a connector 17. Hence, it doesn't need to connect externally to other connectors. Hence, by using the coupling device 100 of the present invention, the test procedure can be performed easily and its cost can be reduced.
(3) The coupling device 100 itself can prevent electric power from leaking. Hence, an additional isolation chamber is not necessary. Hence, by using the coupling device 100 of the present invention, the test procedure can be performed easily and its cost can be reduced.
(4) The coupling device 100 is not complicated in structure, and its components can be made individually and then combined together. Since the coupling device 100 can be designed according to the shape or size of the antenna device 300, the distance between the antenna device 300 and the metal plate 21 can be further reduced via proper design, and the power loss can be further reduced.
(5) The socket 13 of the coupling device 100 has a specific enlarged portion 141. Hence, the coupling device 100 can be prevented from contacting other electronic components of the antenna device 300. The undesired effect caused by contacting the electronic components can thus be avoided.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A coupling device, used to test an antenna device, the coupling device comprising:
a housing having a socket at one side, wherein the socket is capable of receiving the antenna device;
an isolation material disposed inside the socket of the housing, wherein the isolation material has a chamber and a metal plate attached to an inner wall of the chamber; and
a connector disposed at another side of the housing;
wherein the connector is connected to the metal plate and the metal plate is connected to the housing.

2. The coupling device as claimed in claim 1, wherein the housing and the isolation material are designed according to the shape or size of the antenna device.

3. The coupling device as claimed in claim 1, wherein the housing includes a first shell and a second shell, each of the first and second shells has an indentation, and the indentations of the first and second shells are combined to form the socket.

4. The coupling device as claimed in claim 3, wherein each of the indentations of the first and second shells further has an enlarged portion located at a front end of the socket.

5. The coupling device as claimed in claim 3, wherein each of the first and second shells of the housing has a concave portion and the connector is clamped by the concave portions of the first and second shells.

6. The coupling device as claimed in claim 1, wherein the antenna device is plate-shaped.

7. The coupling device as claimed in claim 1, wherein the antenna device is a circuit board having an antenna built therein.

8. The coupling device as claimed in claim 1, wherein the housing is made of aluminum.

9. The coupling device as claimed in claim 1, wherein the housing is made of aluminum alloy.
